(19) United States
(12) Patent Application Publication
(10) Pub. No.: US 2006/0118892 A1
(43) Pub. Date: Jun. 8, 2006

(54) Methods and Structures to Produce a Strain-Inducing Layer in a Semiconductor Device

(75) Inventors: Zhen-Cheng Wu, Hsinchu (TW); Yu-Lien Huang, Jhubei City (TW); Yung-Cheng Lu, Taipei (TW)

Correspondence Address: BAKER & MCKENZIE;ON BEHALF OF TSMC, 2300 TRAMMELL CROW CENTER, 2001 ROSS AVENUE, SUITE 2300, DALLAS, TX, 75201, US

(73) Assignee: TAIWAN SEMICONDUCTOR MANUFACTURING COMPANY, LTD., Hsinchu (TW)

(21) Appl. No.: 10/904,874

(22) Filed: Dec. 2, 2004

(51) Int. Cl. H01L 29/94; H01L 21/3205

(52) U.S. Cl. 257/412; 257/413; 438/585; 438/592

(57) ABSTRACT

Described are methods of manufacturing a strain-inducing layer in semiconductor devices and structures formed to have such strain-inducing layers. Circuit elements are formed on a semiconductor substrate with conductive channel regions within the semiconductor substrate. Metal silicide contacts are formed on the semiconductor substrate and some are electrically connected to the channel regions. A strain-inducing layer can then be formed over the metal silicide contacts. Further, the strain-inducing layer is then treated with thermal processing, photo-thermal processing, or electron irradiation processing thereby increasing the stress of the strain-inducing layer and induce strain upon the crystal lattice structure in the conductive channel regions within the semiconductor substrate.

### BACKGROUND OF THE INVENTION

Semiconductor devices operate by moving free, charged particles through a crystalline lattice structure. Ideally, these moving charged particles would pass through the crystalline lattice of a semiconductor without any collision or other atomic interaction with the lattice, as those interactions will inevitably impede the particles' progress. Accordingly, a material's resistivity (i.e., the material's resistance to the movement of charged particles through a material) will increase with greater particle interaction with the lattice. It is known that a regular crystalline lattice will interact more with free particles in it, and therefore will have a higher resistivity than an irregular crystalline lattice, such as one that is currently under a strain from adjacent materials. Conversely, a strained crystalline lattice will provide a higher charged particle mobility, as demonstrated in a study by Scott E. Thompson et al., A 90-nm Logic Technology Featuring Strained-Silicon, IEEE TRANS. ELEC. DEV., at 1-8 (2004 accepted publication), available at http://ieeexplore.ieee.org/xpl/tocpreprint.jsp?isNumber=21999&puNumber=16.

### SUMMARY OF THE INVENTION

Disclosed are methods for forming strain-inducing layers in semiconductor devices. Circuit elements are formed on a semiconductor substrate with conductive channel regions within the semiconductor substrate. Metal silicide contacts are formed on the semiconductor substrate and some are electrically connected to the channel regions. The metal silicide contacts provide an improved contact resistance relative to non-silicided metallization contacts. As disclosed herein, a strain-inducing layer can then be formed over the metal silicide contacts in order to impart a strain on the crystal lattice structure in channel region (or charge carrying region) of a MOSFET device. As further disclosed herein, the strain-inducing layer can further be treated with thermal processing, photo-thermal processing, or electron irradiation processing in order to further increase the stress imparted by the strain-inducing layer, which in turn more dramatically strains the underlying crystal lattice structure within the channel regions of the semiconductor substrate.

### BRIEF DESCRIPTION OF THE DRAWINGS

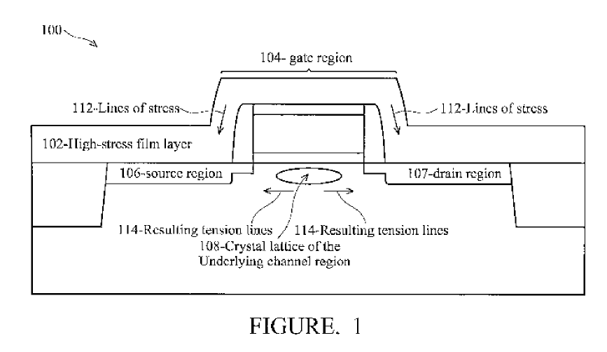

(1) FIG. 1 is a cross-sectional view of a metal oxide semiconductor field effect transistor (MOSFET) device;

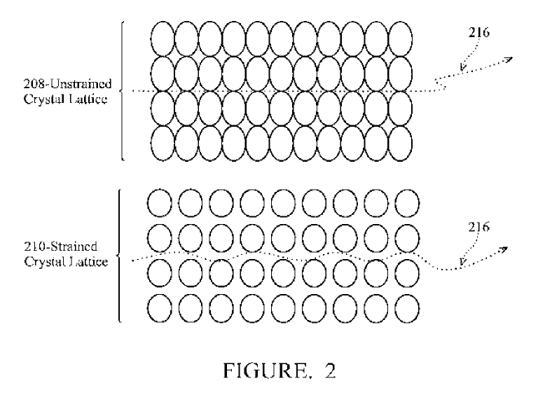

(2) FIG. 2 illustrates charge carrier mobility within an unstrained crystal lattice versus that of a strained crystal lattice;

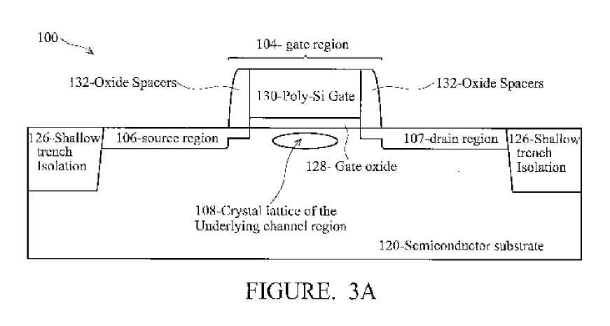

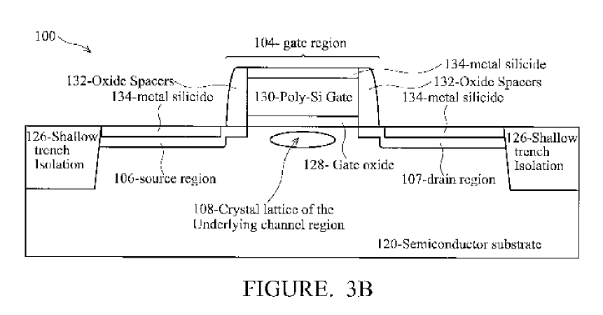

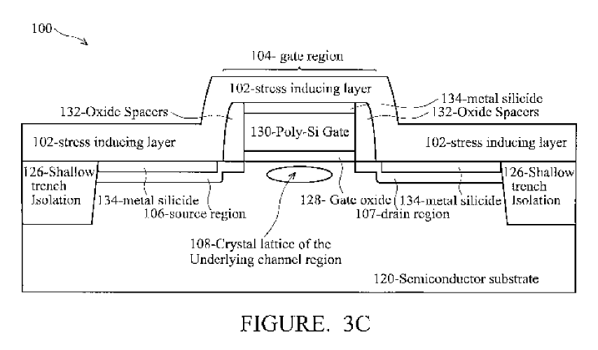

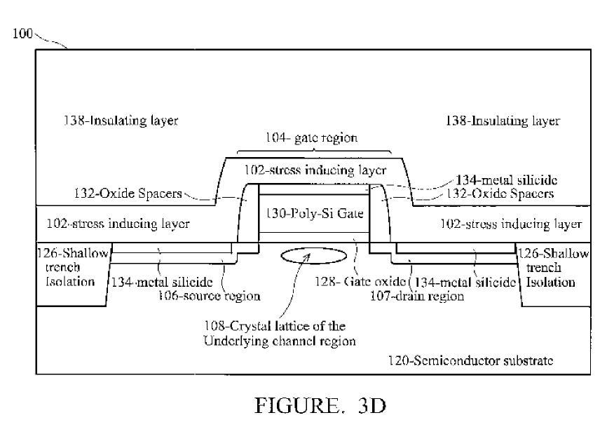

(3) FIG. 3A is a cross-sectional view of a MOSFET device in which a gate with adjacent source and drain regions are formed;

(4) FIG. 3B illustrates the cross-sectional view of the intermediate structure of FIG. 3A upon which metal silicide contacts has been formed;

(5) FIG. 3C illustrates the cross-sectional view of the intermediate structure of FIG. 3B upon which a strain-inducing layer has been formed and treated over the metal silicide contacts;

(6) FIG. 3D illustrates the cross-sectional view of the intermediate structure of FIG. 3C upon which an insulating layer has been formed over the strain-inducing layer;

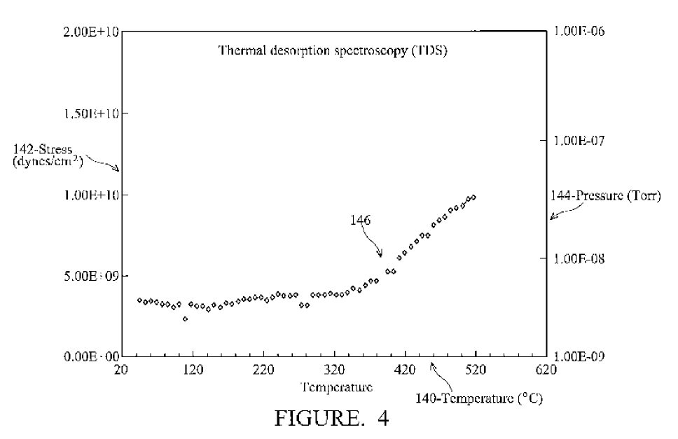

(7) FIG. 4 is a thermal desorption spectroscopy (TDS) measurement illustrating the changes in stress and outgassing when the disclosed treatment process is used;

(8) FIG. 5 is a thermal desorption spectroscopy (TDS) measurement comparing the difference between a strain-inducing layer treated with the disclosed processing embodiments and a strain-inducing layer without the disclosed processing embodiments;

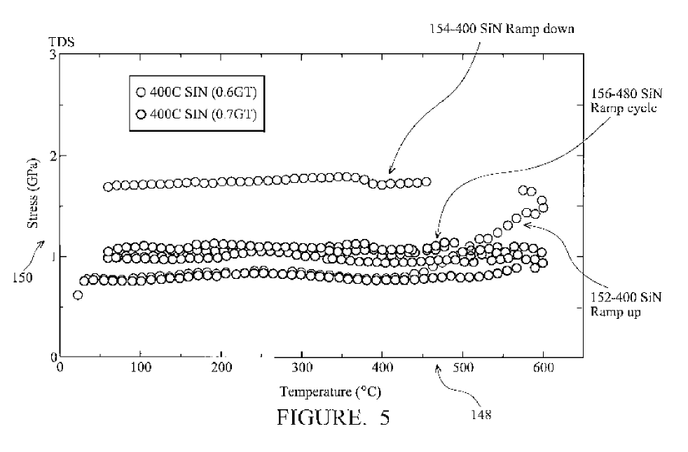

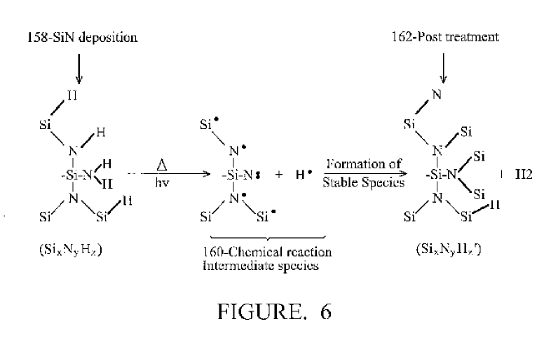

(9) FIG. 6 illustrates the chemical mechanisms involved with the disclosed processing embodiments;

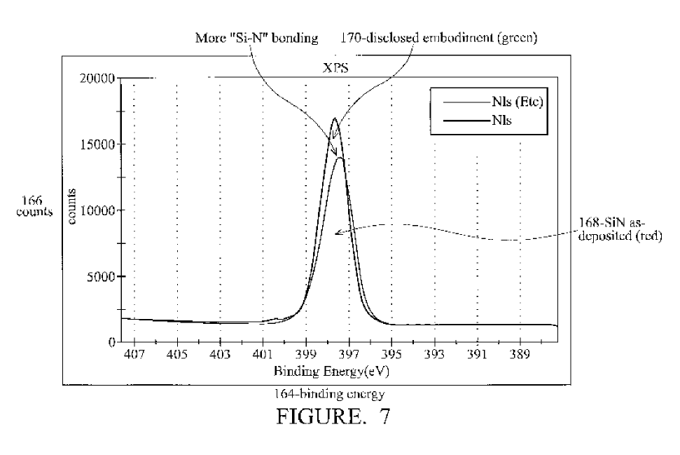

(10) FIG. 7 is a x-ray photoelectron spectroscopy (XPS) measurement comparing the difference between a strain-inducing layer treated with the disclosed processing embodiments and a strain-inducing layer without the disclosed processing embodiments; and

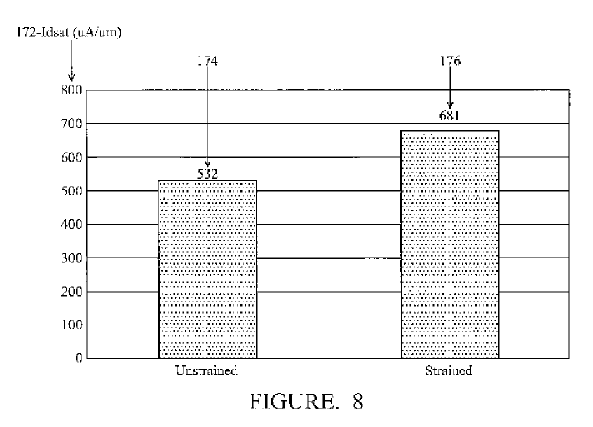

(11) FIG. 8 illustrates the difference in device performance between an unstrained crystal lattice and a strained crystal lattice with the disclosed processing embodiments.

### DETAILED DESCRIPTION OF THE EMBODIMENTS

FIG. 1 is a cross-sectional diagram of a MOSFET transistor 100 in which a high-stress film layer 102 has been overlaid on the gate 104 and source/drain regions 106, 107 in order to impart a strain on the crystal lattice of the underlying channel region 108 of the transistor 100. Lines of stress 112 are drawn to illustrate the stresses built into the interface between the high-stress film layer 102, and the resulting tension lines 114 illustrate that a strain is imparted on the channel region 108 because of the pulling outward by the high-stress film 102 at the interface between the layers. According to Hooke's Law, stress is directly proportional to strain up to some proportionality constant. The above is a very general description of the elements of the MOSFET device 100. A number of the elements shown in this figure but not here described will be described in later figures as the process for forming the strain-inducing layer 102 and the higher carrier mobility MOSFET 100 is more fully described.

While most thin-film depositions will impart some residual strain due to post-deposition cooling or other mechanical or thermal effects, described in this application is a new structure and method for providing an increased stress level and thereby increasing charge mobility in the channel region 108. Charge carriers are the major workhorses of a semiconductor device because they carry the electrical signals as either electrons or holes. Thus, to increase the mobility of these charge carriers is to increase the performance of the semiconductor device.

Further to the discussion about the increases charge carrier mobility seen in a strained crystal lattice, FIG. 2 graphically illustrates the physical phenomenon causing that increase in carrier mobility. An unstrained crystal lattice 208 is relaxed and in its position of lowest potential energy. The tightness of its bonds are maximized, allowing less room for charge carrier mobility, as is shown in the figure.

Unlike the more regular crystalline structure of the unstrained crystal lattice 208, the strained crystal lattice 210 has an expanded crystalline structure that is opened up to allow charge carriers 216 to pass more easily through the structure 210, and those charge carriers 216 will collide less and otherwise interact less with this more irregular structure. As a charge carrier 216 moves through an unstrained crystal lattice 208, its mobility or path of travel is more limited due to interactions and collisions within the regular crystalline orientation. On the other hand, a charge carrier 216 moving through a strained crystal lattice 210 has a much lower probability of these interactions and collisions because of the distorted crystalline orientation. As a result, higher stresses on the film will generally—especially within certain known ranges—provide higher strains in the underlying crystalline structures and will generally provide a higher electron mobility.

Increasing the stress—tensile or compressive—of the stress film 102, which in certain embodiments may be a silicon nitride film, will also generally increase the strain on the crystal lattice. Tensile stress is stress applied to a thin film by pulling or attempting to stretch the film while compressive stress is stress applied to a thin film to compress or to make it fit on the substrate. A film has tensile stress when the stress value is positive, while a film has compressive stress when the stress value is negative. The more positive the stress value, the higher the tensile stress, while the more negative the stress value, the higher the compressive stress.

One of the ways of generating high tensile stress includes processing of the silicon nitride film at high deposition temperatures or at low deposition pressures as described in U.S. Pat. Nos. 6,656,853 and 5,633,202. However, since NiSi, for example, has a low thermal budget and will undergo agglomeration and bridging during high temperature processing, high temperature silicon nitride deposition poses difficulties for creating high tensile stress capping layers in this context. Furthermore, deposition of high tensile stress silicon nitride films at low deposition pressures can result in arcing of the deposition chamber because of the narrow fluctuating process window having to keep the chamber pressure operating constantly at low deposition pressure.

With reference now to FIGS. 3A-3D, a process and resulting structure for a strain-inducing layer 102 that increases strain on an underlying silicon substrate is described.

FIG. 3A is a cross-sectional view of a MOSFET device in which circuit elements such as a gate 104 with adjacent source and drain regions 106, 107 are formed. The source and drain regions 106, 107 are formed on the semiconductor substrate 120 to comprise either n-type or p-type doped regions, according to whether an n-type or p-type MOSFET transistor is desired in a particular design. The n-type implant regions can be formed by implanting phosphorous ions, whereas the p-type implant regions can be formed by implanting boron ions. Known ion implantation techniques have been chosen in order to implant these materials into the underling semiconductor substrate 120. Still referring to FIG. 3A, in addition to forming the source and drain regions 106, 107 inactive regions such as the shallow trench isolations 126 may also be formed to separate one transistor 100 from another employing known ion implantation techniques and methods. A thin gate oxide 128 and a poly-silicon gate 130 are subsequently formed on the semiconductor substrate 120 between the source and drain regions 106, 107 as shown. The crystal lattice structure of interest is located in the conductive channel region 108 underneath the thin gate oxide 128 and between the source and drain regions 106, 107. The source and drain regions 106, 107 are initially formed with shallow implants that are self-aligned with the gate structure. Oxide spacers 132 are then employed prior to deeper source-drain implants, which will give the source/drain regions 106, 107 their characteristic “stepped” profile. By using this structure, it is possible to minimize the encroachment of the channel region by lateral diffusion of the source/drain implants 106, 107. For reduced contact resistance, metal silicide 134 is subsequently formed in the active regions as illustrated in FIG. 3B by known methods and techniques. Nickel is deposited over the silicon and subsequently absorbed therein to form nickel silicide (NiSi) as the preferred silicide material because of its ability to form ultra shallow junctions.

As illustrated in the cross-section of FIG. 3C, a subsequent strain-inducing layer 102 is formed over the gate 104 and source/drain regions 106, 107. While it is not unusual to form an insulating layer over the MOSFET structure at this stage in the process, the present embodiments are selected to provide a new structure and method that provides a higher level of stress in order to increase the charge carrier mobility in the channel region 108. The layer selected as the strain-inducing layer 102 may comprise silicon nitride, silicon oxide, silicon oxynitride, silicon carbide, or silicate glass. In addition, new liquid materials such as spin-on silicate glass and benzocyclobutene may also be employed.

After deposition of the strain-inducing layer 102, and in order to increase the tensile stress of the layer 102, the layer 102 is then subjected to thermal processing, photo-thermal processing, or electron irradiation processing to increase the strain induced by the layer 102 on the crystal lattice in the conductive channel region 108.

Although this layer is described as a stress-inducing layer 102, in a semiconductor device design, this layer may additionally serve the role of an insulating layer or an etch-stop layer, although it is not necessary that this layer provide any such dual role.

After subjecting the stress-inducing layer 102 to thermal processing, photo-thermal processing, or electron irradiation processing, an inter-level dielectric (ILD) layer 138 may be subsequently formed over the stress-inducing layer 102 as illustrated in FIG. 3D. The ILD layer 138 also serves as an insulating layer by operating to passivate the FET device. In addition, the ILD layer 138 also allows the FET device to be planarized or smoothed for additional functionalities and further fabrication processing. The ILD layer 138 may comprise materials and be formed with methods similar to those of and for the stress-inducing layer 102, but it may also be formed using different methods.

Thermal processing of the strain-inducing layer 102 can involve in-situ or ex-situ thermal annealing in a thermal chamber. In-situ thermal processing may be accomplished in either the etch-stop deposition chamber or the inter-level dielectric deposition chamber after deposition of the strain-inducing layer 102 but before deposition of the ILD layer 138. In the present embodiment, the in-situ thermal annealing of the strain-inducing layer 102 is performed at a temperature of between about 400° C. and 700° C. and for a time period of between about 30 seconds and 30 minutes in order to minimize the nickel silicide contacts' 134 exposure to high temperature processing. Ex-situ thermal processing involves thermal annealing in an external thermal chamber under similar annealing conditions as those of in-situ thermal processing. The advantages of an in-situ thermal processing are that there is no extra tool cost associated with it and that it increases throughput in the production line.

In addition to thermal processing, photo-thermal processing may be used to produce a high tensile stress, strain-inducing film 102. Photo-thermal processing involves rapid thermal annealing or ultra-violet (UV) curing. The rapid thermal annealing process is performed at a temperature of between about 800° C. and 1,500° C. with a broadband halogen lamp radiation source at a wavelength between about 500 nm and 1500 nm and for a time period of between about 5 seconds and 10 minutes. Although the silicide contacts 134 are exposed to higher processing temperatures, the exposure time has been substantially limited compared to conventional high temperature processing to minimize bridging or agglomerating of the silicide contacts 134. In addition to the thermal effects, the rapid thermal annealing process also receives a contribution from the broadband halogen lamp radiation source to help increase the tensile stress in the strain-inducing layer 102.

The other photo-thermal processing involves UV curing which is performed at a temperature of between about 400° C. and 600° C. with an UV-visible lamp radiation source at a wavelength between about 100 nm and 700 nm and for a time period of between about 30 seconds and 30 minutes. Like with rapid thermal annealing process, the UV light photons also contribute to increasing the tensile stress of the strain-inducing layer 102. However, unlike the rapid thermal annealing process, UV curing is performed at relatively low temperatures and will further minimize bridging or agglomerating of the silicide contacts 134.

In addition to thermal processing and photo-thermal processing, electron irradiation may be employed involving electron-beam curing at a temperature of between about 400° C. and 700° C. with an electron energy between about 0.5 KeV and 10.0 KeV at an electron dosage between about 10 mC/cm² and 200 mC/cm² and for a time period of between about 30 seconds and 30 minutes. Like with photo-thermal processing, the combination of the electrons irradiating the surface of the strain-inducing layer 102 and the corresponding thermal annealing of the film give rise to an increased tensile stress in the layer 102.

In one embodiment, the deposition process for forming the strain-inducing layer 102 on the wafer involves chemically reacting two or more materials in gaseous form within an enclosed chamber. Such gases may include silane, oxygen, nitrogen, fluorinated gases, or phosphine gases. Silane (SiH₄) gas is an example of a heteronuclear diatomic molecule because it is composed of two different elements, silicon and hydrogen. Oxygen (O₂) and nitrogen (N₂) gases, on the other hand, are examples of mononuclear diatomic molecules because they are composed of only one type of element, either oxygen or nitrogen. The mechanism behind the increase in tensile stress of the strain-inducing layer 102 is that thermal annealing and light photon breaks the weak heteronuclear diatomic Si—H and N—H bonds (silicon nitride is the strain-inducing layer 102 in the present embodiment) and causes the layer 102 to undergo rearrangement to a different structure as illustrated by thermal desorption spectroscopy (TDS) in FIG. 4. TDS is an analytical technique utilized to measure the stress and outgassing in a sealed environmental vacuum chamber. The stress is measured utilizing a laser based on the curvature of the film, while outgassing is a measure of how much gas is released from the surface of the film. In this TDS measurement, the temperature 140 is plotted on the x-axis in degree Celsius (°C.) increasing from left to right, the stress 142 is plotted on the left y-axis in dynes per centimeter squared (dynes/cm²) increasing from bottom to top, and the pressure 144 is plotted on the right y-axis in Torr increasing from bottom to top.

As illustrated by the TDS scan 146 of the disclosed processing embodiments in FIG. 4, the strain-inducing layer 102 experiences increased stress 142 and increased outgassing pressure 144 with increasing temperature 140 as evidenced by the upward curvature as the temperature of the device increases beyond around 400° C. As the temperature 140 of the thermal annealing increases, the stress 142 increases exponentially from around 0.5 GPa (5.00 E+09 dynes/cm²) at a temperature 140 of around 400° C. up to a stress 142 of around 1.0 GPa (1.00 E+10 dynes/cm²) at a temperature 140 of around 500° C. The increase in stress 142 is due to the change in the composition of the silicon nitride (the strain-inducing layer 102 in the present embodiment) as the heteronuclear diatomic Si—H and N—H bonds are being broken and mononuclear diatomic H—H (H₂) hydrogen gas bonds are being formed. As a result of the chemical bond breaking and film rearrangement, there will be an increase in pressure due to outgassing of the hydrogen gas as illustrated by the exponential increase in pressure 144 from about 3.00 E-09 Torr at a temperature 140 of around 400° C. up to a pressure 144 of about 3.00 E-08 Torr at a temperature 140 of around 500° C.

In another embodiment, the strain-inducing layer 102 is formed by a spin-on-glass deposition process, in which a glass layer comprising, for example, phosphorous and/or boron in addition to silicon is deposited. The layer 102 formed in this embodiment also may include heteronuclear diatomic bonds, although it is possible that these bonds would be initially diminished relative to the gaseous deposition processes due to the nature of the spin-on-glass technique. In this embodiment, the strain would be induced either by the outgassing of gas bonds or perhaps through cooling of the glass layer 102, post-deposition.

Benefits of the disclosed methods are further illustrated in FIG. 5 with a side-by-side comparison between a layer treated with the disclosed processing embodiments and such a layer to which the disclosed processing embodiments have not been applied. FIG. 5 is another TDS measurement similar to that of FIG. 4 with the temperature 148 plotted on the x-axis in degree Celsius (°C.) increasing from left to right and the stress 150 plotted on the y-axis in Giga-Pascal (GPa) increasing from bottom to top. The strain-inducing layer 102 treated with the disclosed thermal processing embodiment (152 and 154) displayed two different cycles during TDS testing, a ramp-up cycle 152 and a ramp-down cycle 154. Meanwhile, the strain-inducing layer 102 without the disclosed treatment 156 displayed only one cycle during the ramp up and ramp down.

As illustrated in FIG. 5, the strain-inducing layer 102 without the disclosed processing embodiments 156 demonstrated no significant increases or decreases in stress 150 with increasing or decreasing temperature 148. The stress 150 of the strain-inducing layer 102 without the disclosed treatment 156 stayed relatively flat around 1 GPa when the temperature 148 was ramped up from about 100° C. up to 600° C., and it stayed relatively flat around 1 GPa when the temperature 148 was ramped down from 600° C. to 100° C. This illustrates that no chemical bond breaking and film rearrangement is taking place within the strain-inducing layer 102, and therefore the strain-inducing layer 102 without the disclosed processing embodiments 156 illustrated no substantial increase in tensile stress.

On the other hand, the strain-inducing layer 102 with the disclosed processing embodiments (152 and 154) experienced two thermal cycles. The ramp-up cycle 152 in FIG. 5 is similar to that of FIG. 4 where as the temperature 148 of the thermal annealing increases, the stress 150 also increased. In FIG. 5, the stress 150 of the ramp-up cycle 152 increased gradually from around 0.7 GPa at a temperature 148 of around 400°C. up to a stress 150 of around 1.5 GPa at a temperature 148 of around 600° C. The increase in stress 150 is due to the change in the composition of the strain-inducing layer 102 as the heteronuclear diatomic Si—H and N—H bonds are being broken and mononuclear diatomic H—H (H₂) hydrogen gas bonds are being formed (silicon nitride is the strain-inducing layer 102 in the present embodiment). The bond breaking and bond rearrangement mechanism is confirmed by the ramp-down cycle 154 as the stress 150 of the strain-inducing layer 102 stayed relatively constant at around 1.5 GPa when the temperature 148 is ramped down from 600° C. to 100° C. The stability in the stress 150 of around 1.5 GPa exhibited by the ramp-down cycle 154 is further evidence that the bond breaking and rearrangement is completed thereby leading to a permanent increase in the tensile stress of the strain-inducing layer 102.

The chemical mechanism behind correlating the increased stress due to chemical bond breaking and rearrangement can be explained by FIG. 6. Silicon nitride may be used as the strain-inducing layer 102 and can be formed by the reaction of silane and nitrogen. The as-deposited silicon nitride strain-inducing layer 102 has a chemical structure 158 containing several heteronuclear diatomic Si—N, Si—H, and N—H bonds as illustrated in FIG. 6. Upon processing of the as-deposited silicon-nitride strain-inducing layer 102 with the disclosed embodiments, a post treatment species 162 of mostly heteronuclear diatomic Si—N bonds is formed. As a result of the increased energy from thermal, photo-thermal, or electron irradiation utilizing the disclosed embodiments, the heteronuclear diatomic N—H and Si—H bonds from the as-deposited chemical structure 158 are broken and an intermediate species 160 is formed. The intermediate species 160 show several Si. and N. radicals as well as H. radicals. These intermediate species 160 subsequently re-arranges to form stable species resulting in a chemical structure 162 with an increased number of heteronuclear diatomic Si—N bonds and mononuclear diatomic H—H bonds being formed. The newly formed Si-N bonds have higher bond strength because they comprise a more thermodynamically stable species than those with Si—H or N—H bonds. The increased Si—N bond strength also means a decreased Si—N bond length because the Si and N atoms now have the ability to pack in closer and tighter together. In addition, decreased bond length translates into increased thermal stability because mononuclear diatomic hydrogen gas 162 has been driven out (outgassing) of the film. As a result, a thermally stable strain-inducing layer 102 utilizing the disclosed silicon nitride embodiments will exhibit increased tensile stress compared to a silicon nitride layer 102 processed without the disclosed embodiments.

Further confirmation of the increased stress as a result of the increasing number of Si—N bonds may be achieved by examining the difference in film property between that of an as-deposited silicon nitride film 102 and a treated silicon nitride film 102 that has been strained utilizing the disclosed embodiments. X-ray photoelectron spectroscopy (XPS) is a quantitative technique for determining film composition based on the photoelectric effect whereby a sample is subjected to photons resulting in electron excitation thereby producing an energy signature. FIG. 7 is a XPS measurement comparing the difference between a strain-inducing layer 102 treated with the disclosed processing embodiments and a strain-inducing layer 102 without the disclosed processing embodiments. In FIG. 7, the binding energy 164 measured in electron volts (eV) is plotted on the x-axis increasing from right to left while the counts 166 is plotted on the y-axis increasing from bottom to top. The binding energy 164 is the energy signature, which corresponds to a specific chemical bond while the count 166 is a measure of the number of excited electrons. Consequently the higher the count 166, the greater are the number of excited electrons and therefore the more the number of the specific chemical bonds. The as-deposited 168 silicon nitride strain-inducing film 102 and the silicon nitride strain-inducing film 102 that has been treated with the disclosed embodiments 170 are illustrated. With the Si—N bond having a binding energy 158 of around 398 eV, the XPS depicts an increased count 166 of Si—N bonds for the stressed silicon nitride film 102 with the disclosed embodiment 170 versus that of the as-deposited silicon nitride film 102 without the use of disclosed embodiments 168. The increased number of Si—N bonds, as explained earlier, correlates with the increased stress in the film as a result of the silicon nitride film 102 being strained after being treated with the disclosed embodiments.

As discussed earlier, the higher the tensile stress of the strain-inducing layer 102, the higher the strain exerted on the crystal lattice, and consequently the higher the charge carrier mobility. FIG. 8 compares the device performance between a transistor having an unstrained crystal lattice in its channel region relative to one having a strained crystal lattice in its channel region where the strained lattice is imparted by utilizing the disclosed processing embodiments. In FIG. 8, the drain saturation current (Idsat) 172 is plotted on the y-axis in units of microamperes per micron (micro A/micro m) increasing from bottom to top. The drain saturation current 172 scales proportionally with the charge carrier mobility and is a good measure of the electrical performance of a device, with the higher the drain saturation current 172 the higher the carrier mobility. From FIG. 8, a transistor containing the unstrained crystal lattice 174 has a measured drain saturation current of 532 micro A/micro m while that of the strained crystal lattice 176 has a measured drain saturation current of 681 micro A/micro m. A stress-inducing layer 102 formed with the disclosed processing embodiments has been measured to induce the crystal lattice in the channel region 108 to a performance improvement of nearly 30% compared to conventional crystal lattice without the induced strain, although performance improvements of more or less than this amount may be feasible, and a performance improvement of 10% or 20% would obviously still be a welcome performance improvement and achievable using the described processing techniques and strain-inducing layers 102.

Although the above descriptions are for particular embodiments, none of those embodiments are intended to be limits upon the scope of the various inventions that are set forth in the attached claims. Various additional embodiments are possible and can still fall within the scope of the appended claims. In other words, the above descriptions are intended to be illustrative and not restrictive. For example, although the strained crystal lattice is commonly located within the conductive channel regions within a semiconductor substrate, the crystal lattice may be on thin lightly doped p-silicon layers grown on buried silicon dioxide on top of a silicon substrate such as would be employed in a silicon-on-insulator application. In addition, although the described substrate 120 is silicon, other substrates 120 such as silicon germanium (SiGe), gallium arsenide (GaAs), indium phosphide (InP), gallium nitride (GaN), and silicon carbide (SiC) may be also be chosen as substrates due to their low thermal tolerance.

The scope of the invention is indicated by the appended claims rather than the foregoing description, and all changes that come within the meaning and ranges of equivalents thereof are intended to be embraced therein.

Additionally, the section headings herein are provided for consistency with the suggestions under 37 C.F.R. § 1.77 or otherwise to provide organizational cues. These headings shall not limit or characterize the invention(s) set out in any claims that may issue from this disclosure. Specifically and by way of example, although the headings refer to a “Technical Field,” the claims should not be limited by the language chosen under this heading to describe the so-called technical field. Further, a description of a technology in the “Background” is not to be construed as an admission that technology is prior art to any invention(s) in this disclosure. Neither is the “Summary of the Invention” to be considered as a characterization of the invention(s) set forth in the claims found herein. Furthermore, any reference in this disclosure to “invention” in the singular should not be used to argue that there is only a single point of novelty claimed in this disclosure. Multiple inventions may be set forth according to the limitations of the multiple claims associated with this disclosure, and the claims accordingly define the invention(s), and their equivalents, that are protected thereby. In all instances, the scope of the claims shall be considered on their own merits in light of the specification, but should not be constrained by the headings set forth herein.

1. (canceled)

2. (canceled)

3. (canceled)

4. (canceled)

5. (canceled)

6. (canceled)

7. A method of manufacturing a semiconductor device comprising circuit elements formed on a semiconductor substrate and conductive channel regions within the semiconductor substrate, the method comprising:
forming metal silicide contacts on the semiconductor substrate;
forming a strain-inducing layer over and in contact with the metal silicide contacts;
treating the strain-inducing layer with thermal processing while exposed to increase a tensile stress of the strain-inducing layer and thereby inducing expansive strain upon the crystal lattice structure in the conductive channel regions within the semiconductor substrate.

8. The method according to claim 7, wherein the metal silicide contacts comprise a material selected from the group consisting of nickel silicide, cobalt silicide, platinum silicide, titanium silicide, tungsten silicide, and molybdenum silicide.

9. The method according to claim 7, wherein the strain-inducing layer is formed by a deposition technique selected from the group consisting of plasma-enhanced chemical vapor deposition, low-pressure chemical vapor deposition, and high-density plasma chemical vapor deposition.

10. The method according to claim 7, wherein the strain-inducing layer is formed substantially of a material selected from the group consisting of silicon nitride, silicon oxide, silicon oxynitride, silicon carbide, undoped silicate glass, phosphorous doped silicate glass, and mixtures of undoped silicate glass and phosphorous doped silicate glass.

11. The method according to claim 7, wherein the strain-inducing layer is formed substantially of a spin-on material selected from the group consisting of undoped silicate glass, phosphorous doped silicate glass, undoped silicate glass and phosphorous doped silicate glass, and benzocyclobutene.

12. The method according to claim 7, wherein the thickness of the strain-inducing layer is between about 50 Å and 2,000 Å.

13. The method according to claim 7, wherein the thermal processing comprises thermal annealing techniques selected from the group consisting of:
in-situ thermal annealing in the strain-inducing layer deposition chamber after deposition of the strain-inducing layer at a temperature of between about 400° C. and 700° C. and for a time period of between about 30 seconds and 30 minutes;
in-situ thermal annealing in an insulating layer deposition chamber before deposition of an insulating layer over the strain-inducing layer at a temperature of between about 400° C. and 700° C. and for a time period of between about 30 seconds and 30 minutes; and
thermal annealing in an external chamber after deposition of the strain-inducing layer but before deposition of an the insulating layer over the strain-inducing layer at a temperature of between about 400° C. and 700° C. and for a time period of between about 30 seconds and 30 minutes.

14. The method according to claim 7, wherein the thermal processing is photo-thermal processing comprising rapid thermal annealing at a temperature of between about 800° C. and 1,500° C. with a broadband halogen lamp radiation source at a wavelength between about 500 nm and 1500 nm and for a time period of between about 5 seconds and 10 minutes.

15. The method according to claim 7, wherein the processing is photo-thermal processing comprising ultra-violet (UV) curing at a temperature of between about 400° C. and 600° C. with an UV-visible lamp radiation source at a wavelength between about 100 nm and 700 nm and for a time period of between about 30 seconds and 30 minutes.

16. The method according to claim 7, wherein the thermal processing is electron radiation processing comprising is electron-beam curing at a temperature of between about 400° C. and 700° C. with an electron energy between about 0.5 KeV and 10.0 KeV at an electron dosage between about 10 mC/cm² and 200 mC/cm² and for a time period of between about 30 seconds and 30 minutes.

17. The method according to claims 7, wherein the strain-inducing layer comprises silicon nitride comprising heteronuclear diatomic N—H and Si—H bonds, and wherein treating the strain-inducing layer with thermal processing while exposed to increase a tensile the stress of the strain-inducing layer comprises increasing a temperature of the exposed silicon nitride strain-inducing layer after its deposition sufficient to decrease N—H and Si—H bonds and increase Si—N and H—H bonds in the silicon nitride strain-inducing layer.

18. The method according to claims 17, wherein treating the stain-inducing layer comprises with thermal process sufficient to increase a tensile stress of the strain-inducing layer to about +1.5 GPa and to maintain the tensile stress of about +1.5 GPa after ceasing the thermal processing.

19. The method according to claims 7 wherein the conductive channel regions within the semiconductor substrate comprise source/drain regions of a semiconductor device.

20. The method according to claims 19, wherein the semiconductor device comprise a metal-oxide-semiconductor field-effect transistor.
